(19) United States
(12) Patent Application Publication
(10) Pub. No.: US 2015/0011031 A1
(43) Pub. Date: Jan. 8, 2015

(54) METHOD OF MANUFACTURING ORGANIC LIGHT EMITTING DIODE

(71) Applicant: Electronics and Telecomunications Research Institute, Daejeon (KR)

(72) Inventors: Doo-Hee CHO, Daejeon (KR); Jin Wook SHIN, Daejeon (KR); Jeong Ik LEE, Daejeon (KR); Hye Yong CHU, Daejeon (KR); Jonghee LEE, Daejeon (KR); Jaehyun MOON, Daejeon (KR); Seung Koo PARK, Daejeon (KR)

(73) Assignee: Electronics and Telecomunications Research Institute, Daejeon (KR)

(21) Appl. No.: 14/271,925

(22) Filed: May 7, 2014

(30) Foreign Application Priority Data
Jul. 2, 2013 (KR) 10-2013-0076994
Dec. 3, 2013 (KR) 10-2013-0149227

(51) Int. Cl. H01L 51/52

(52) U.S. Cl. CPC H01L 51/5268
USPC 438/29

(57) ABSTRACT

Provided is a method of manufacturing an organic light emitting diode. The method of manufacturing an organic light emitting diode includes forming a light scattering layer on a substrate, forming a metal mask layer on the light scattering layer, forming a metal mask pattern by performing a heat treatment process on the metal mask layer, forming a nano structure by pattering the light scattering layer by using the metal mask pattern as an etching mask, and forming a planarizing layer to cover the nano structure on the substrate, wherein the heat treatment process is performed at temperature of about 80° C. to about 200° C.

### CROSS-REFERENCE TO RELATED APPLICATIONS

This U.S. non-provisional patent application claims priority under 35 U.S.C. §119 of Korean Patent Application No. 10-2013-0076994, filed on Jul. 2, 2013, 10-2013-0149227, filed on Dec. 3, 2013, the entire contents of which are hereby incorporated by reference.

### BACKGROUND OF THE INVENTION

The present invention disclosed herein relates to a method of manufacturing an organic light emitting diode, and more particularly, to a method of manufacturing an organic light emitting diode including a light scattering layer.

Recently, there is an increase in demand for lightweight, miniaturization, and low price in electronic products such as mobile phones, or notebooks and lighting devices. In order to meet these demands, organic light emitting devices attract attention as display devices and light emitting devices mounted in the electronic products and lighting devices. In particular, organic light emitting devices have advantages in low voltage driving performance, lightweight, and low cost, and thus have utilization in the electronic products and lighting devices.

Nowadays, increasing light emitting efficiency of an organic light emitting device is being researched. In particular, various researches are performed on increasing light emitting efficiency of an organic light emitting device even in a low voltage by extracting a light lost inside the organic light emitting device externally.

### SUMMARY OF THE INVENTION

The present invention provides a method of manufacturing an organic light emitting device having improved light extraction efficiency.

The present invention also provides a method of manufacturing an organic light emitting device that is able to be easily manufactured at a low cost.

Embodiments of the present invention provide methods of manufacturing an organic light emitting diode, including: forming a light scattering layer on a substrate; forming a metal mask layer on the light scattering layer; forming a metal mask pattern by performing a heat treatment process on the metal mask layer; forming a nano structure by pattering the light scattering layer by using the metal mask pattern as an etching mask; and forming a planarizing layer to cover the nano structure on the substrate, wherein the heat treatment process is performed at temperature of 80° C. to about 200° C.

In some embodiments, the heat treatment process may be performed in a vacuum state.

In other embodiments, the heat treatment process may be performed in an inert gas atmosphere.

In still other embodiments, the heat treatment process may be performed in an inert gas atmosphere.

In even other embodiments, the light scattering layer has a smaller refractive index than the substrate.

In even other embodiments, the refractive index of the light scattering layer may be about 1.1 to about 1.5.

In yet other embodiments, the light scattering layer may include fluorine resin, silicone oxide, magnesium oxide, or a combination thereof.

In further embodiments, the nano structure may include a plurality of nano patterns protruding in a vertical direction to a top surface of the substrate; and recess regions defined by side walls of the plurality of nano patterns, wherein a height of the plurality of nano patterns is defined as a distance between a top surface of the nano patterns and a bottom surface of the recess regions, and the height of the nano patterns is about 150 nm to 600 nm.

In still further embodiments, the metal mask pattern may include openings exposing the light scattering layer, and the forming of the nano structure comprises forming the recess regions by etching the light scattering layer exposed by the openings.

In even further embodiments, the method may further include removing the metal mask pattern after the forming of the nano structure, wherein the metal mask pattern is removed by using an acid solution.

In yet further embodiments, the acid solution may include nitric acid, sulfuric acid, aqua regia, or phosphoric acid.

In much further embodiments, the method may further include: forming a first electrode on the planarizing layer; forming an organic light emitting layer on the first electrode; and forming a second electrode on the organic light emitting layer, wherein the planarizing layer has substantially the same refractive index as the first electrode.

In still much further embodiments, the method may further include: forming a first electrode on the planarizing layer; forming a second electrode on an organic light emitting layer on the first electrode; and forming a second electrode on the organic light emitting layer, wherein the planarizing layer has a greater refractive index than the first electrode.

In even much further embodiments, the refractive index of the planarizing layer may be about 1.8 to about 2.5.

In yet much further embodiment, the method may further include forming a polymer film between the substrate and the light scattering layer, wherein the polymer film comprises at least one of polyacrylic, polyimide, polycarbonate, perylene, polyethylene, and polystyrene.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a flow chart illustrating a method of manufacturing an organic light emitting diode according to embodiments of the present invention;

FIGS. 2 to 4, and FIGS. 6 to 8 are cross-sectional views illustrating a method of an organic light emitting diode according to an embodiment of the present invention ;

FIG. 5 is a plan view of a metal mask pattern according to an embodiment of the present invention;

FIG. 9 is a plan view of a metal mask pattern according to an embodiment of the present invention;

FIG. 10 is a cross-sectional view illustrating a method of manufacturing an organic light emitting diode according to another embodiment of the present invention;

FIG. 11 is a cross-sectional view illustrating a method of manufacturing an organic light emitting diode according to another embodiment of the present invention;

FIGS. 12 to 16 are scanning electron microscope (SEM) images of metal mask patterns according to heat treatment conditions; and

FIG. 17 is a graph representing an increase rate of light extraction according to a height of nano patterns.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the dimensions of layers and regions are exaggerated for clarity of illustration. Like reference numerals refer to like elements throughout.

The terminology used herein is for the purpose of describing particular embodiments only and is not intended to be limiting of the invention. Unless otherwise defined, all terms used herein have the same meaning as commonly understood by one of ordinary skill in the art to which this invention pertains, and should not be interpreted as having an excessively comprehensive meaning nor as having an excessively contracted meaning. Hereinafter, it will be described about an exemplary embodiment of the present invention in conjunction with the accompanying drawings.

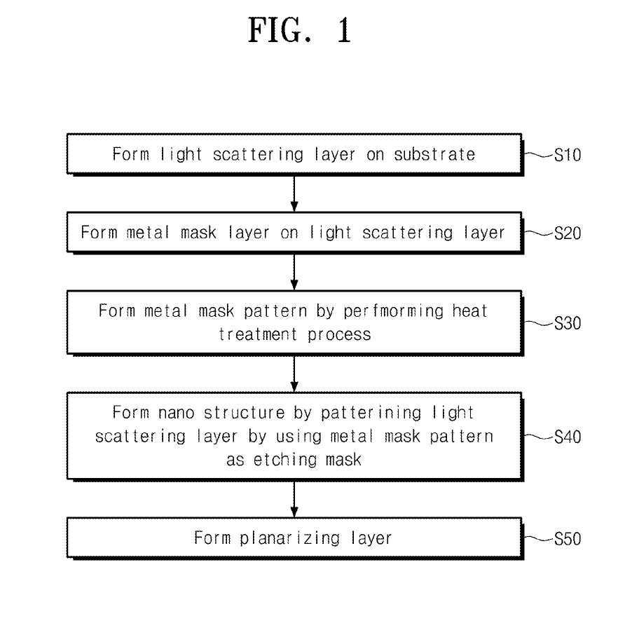

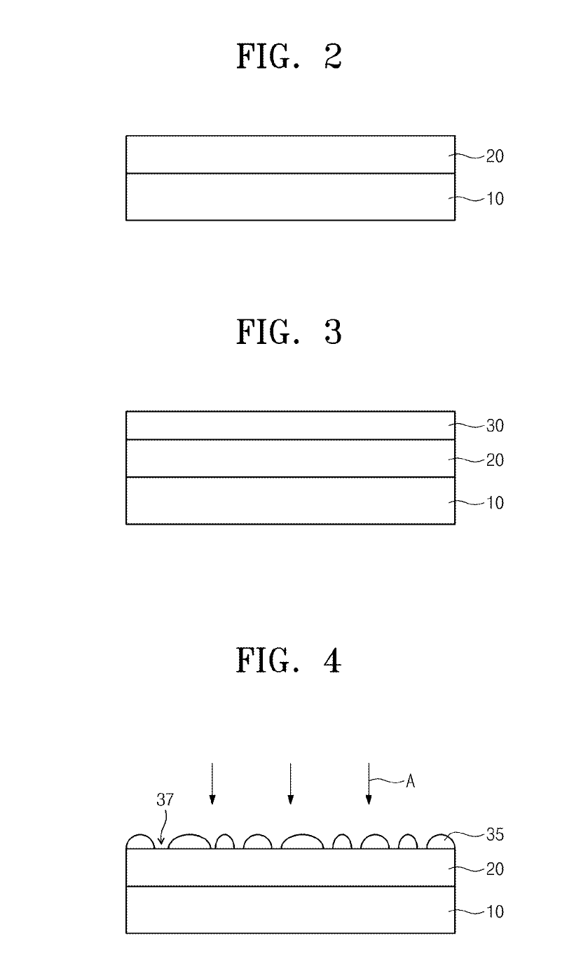

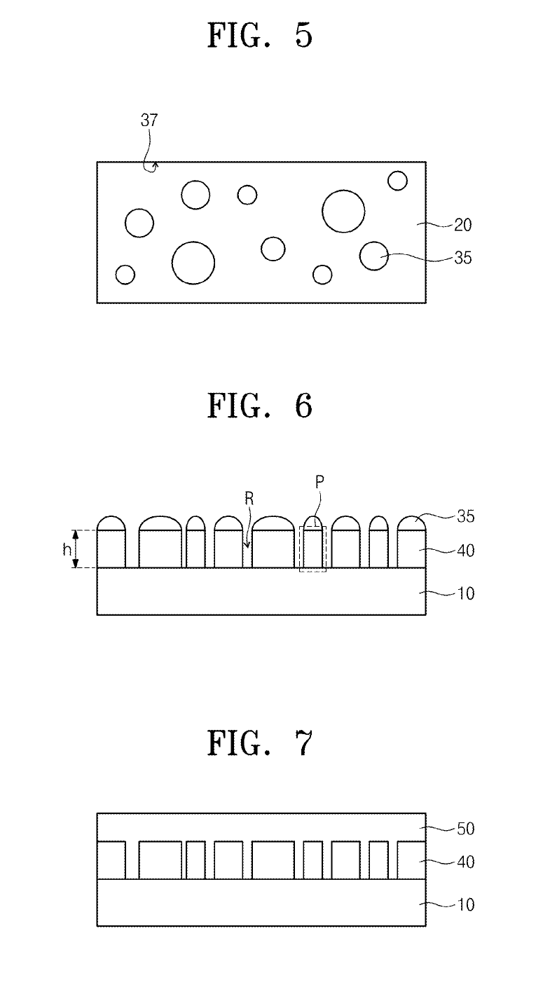

FIG. 1 is a flowchart illustrating a method of manufacturing an organic light emitting diode according to embodiments of the present invention. FIGS. 2 to 4, and FIGS. 6 to 8 are cross-sectional views illustrating a method of manufacturing an organic light emitting diode according to an embodiment of the present invention. FIG. 5 is a plan view of a metal mask pattern according to an embodiment of the present invention.

Referring to FIGS. 1 and 2, a light scattering layer 20 may be formed (S10) on a substrate 10. The substrate 10 may be made from a transparent material such as a glass, quartz, or a plastic. The substrate 10 may have a refractive index of about 1.5 to about 1.6. The light emitting layer 20 may have a lower refractive index than the substrate 10. The light scattering layer 20 may have a refractive index of about 1.1 to about 1.5. The light scattering layer 20 may include fluorine resin, silicone oxide, magnesium oxide, or a combination thereof. The light scattering layer 20 may be provided as having about 100 nm to about 1000 nm thickness on the substrate 10.

Referring to FIGS. 1 and 3, a metal mask layer 30 may be formed (S20) on the light scattering layer 20. The metal mask layer 30 may include, for example, silver or a silver alloy. The metal mask layer 30 may be provided as having about 30 nm to 200 nm thickness on the light scattering layer 20. The metal mask layer 30 may be formed by using, for example, a sputtering deposition process.

Referring to FIGS. 1 and 4, a metal mask pattern 35 may be formed (S30) by performing a heat treatment process A on the metal mask layer 30. In detail, the metal mask pattern 35 may be formed by using a dewetting phenomenon of the metal mask layer 30 in the heat treatment process A. The metal mask pattern 35 may have openings 37 exposing the light scattering layer 20.

The heat treatment process A may be performed in a vacuum state or an inert gas atmosphere (for example, a nitride atmosphere). Accordingly, compared to a case where the heat treatment process A is performed in the air, the heat treatment process A may be performed at relatively low temperature. The heat treatment process A may be performed at temperature of about 80° C. to about 200° C. When the heat treatment process A is performed at temperature lower than about 80° C., the dewetting phenomenon of the metal mask layer 30 does not sufficiently occur, and it may be accordingly difficult to form the metal mask pattern 35. When the treatment process A is performed at temperature higher than about 200° C., yellowing and cracks may occur in the substrate 10 and the light scattering layer 20 disposed under the metal mask layer 30 during the heat treatment process A.

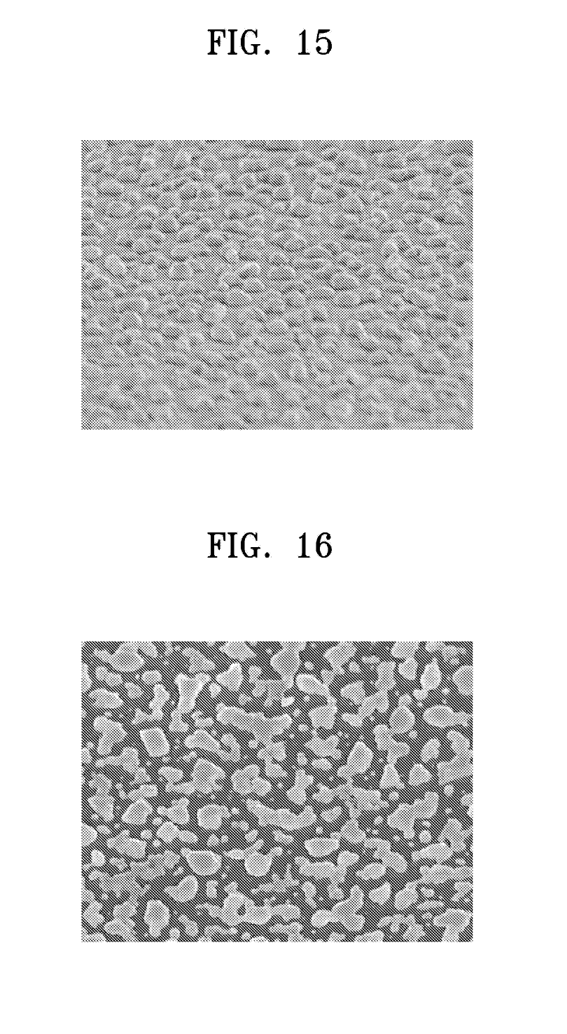

FIGS. 12 to 16 are scanning electron microscope (SEM) images of metal mask patterns according to heat treatment conditions.

### Comparative Example

First, a light scattering layer was formed which includes silicon oxide on a soda-lime glass substrate. A comparative sample was manufactured by forming a metal mask layer including a silver alloy on the light scattering layer, and then heat-treating the metal mask layer for 30 minutes at temperature of about 250° C. in the air. FIG. 12 is a SEM image of the comparative sample. Referring to FIG. 12, since the dewetting phenomenon does not sufficiently occur, it may be confirmed that only metal oxide that the metal mask layer is partially oxidized is formed on the surface of the metal mask layer, and a metal mask pattern is not formed.

### Experimental Example

First, a light scattering layer was formed which includes silicon oxide on a soda-lime glass substrate and then a metal mask layer including a silver alloy was formed on the light scattering layer. Thereafter, experimental samples are heat-treated according to conditions described below.

1) Experimental sample 1 was heat-treated for 2 hours at temperature of about 200° C. in a vacuum oven.

2) Experimental sample 2 was heat-treated for 10 minutes at temperature of about 180° C. on a heating plate in a nitride atmosphere.

3) Experimental sample 3 was heat-treated for 1 hour at temperature of about 160° C. in a vacuum oven.

4) Experimental sample 4 was heat-treated for 1 hour at temperature of about 120° C. in a vacuum oven.

FIGS. 13 to 16 are SEM images of the experimental samples 1 to 4, respectively. Referring to FIGS. 13 to 16, although the experimental samples are heat-treated at relatively low temperature compared to the comparative sample, it can be confirmed that metal mask patterns are formed due to occurrences of the dewetting phenomena of the metal mask layers.

FIG. 5 is a plan view of a metal mask pattern according to an embodiment of the present invention. According to the embodiment, as shown in FIG. 5, the metal mask pattern 35 may include a plurality of patterns formed on the light scattering layer 20. The plurality of patterns may have island types respectively. In this case, the plurality of patterns may be formed separately from each other by one opening 37.

Referring to FIGS. 1 and 6, a nano structure 40 may be formed (S40) by patterning the light scattering layer 30 by using the metal mask pattern 35 as an etching mask. The forming of the nano structure 40 may include forming recess regions R by etching the light scattering layer 20 exposed by the openings 37 of the metal mask pattern 35.

According to an embodiment, the forming of the recess regions R may include dry-etching the light scattering layer 20. The dry etching process may be, for example, a reactive ion etching or inductively coupled plasma etching process. The recess regions R may be formed to expose a part of top surface of the substrate 10.

The nano structure 40 may have a plurality of nano patterns P protruding in a vertical direction on the top surface of the substrate 10, and the recess regions R may be defined by side walls of the nano patterns P. A height h of the nano patterns P, which is defined to be a distance between the top surface of the nano patterns P and the bottom surface of the recess regions R, may be about 150 nm to about 600 nm.

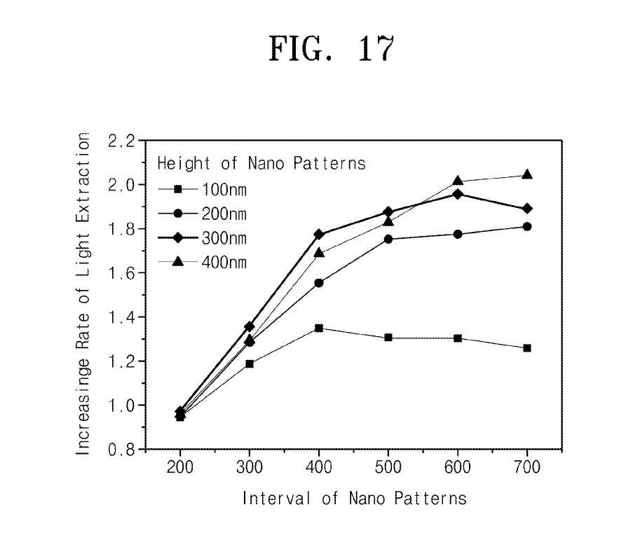

FIG. 17 is a graph representing an increase rate of light extraction according to a height of the nano patterns. Referring to FIG. 17, it can be confirmed that light extraction efficiency is significantly improved when the height of the nano patterns P is about 200 nm or higher, compared to a case where the height of the nano patterns P is about 100 nm.

According to a concept of the present invention, the metal mask pattern 35 may be easily formed at relatively low temperature. The nano structure 40 may be easily formed which includes the nano patterns P having relatively high height by using the metal mask pattern 35. Accordingly, an organic light emitting diode having improved light extraction efficiency may be easily manufactured at a low cost.

Referring to FIGS. 1 and 7, first, the metal mask pattern 35 may be removed. The metal mask pattern 35 may be removed by using an acid solution. As the metal mask pattern 35 is removed by using the acid solution, the nano structure 40 may be prevented from being damaged. The acid solution may include, for example, nitric acid, sulfuric acid, aqua regia, or phosphoric acid.

Furthermore, a planarizing layer 50 may be formed (S50) to cover the nano structure 40 on the substrate 10. The planarizing layer 50 may fill the recess regions R of the nano structure 40 and cover the top surface of the nano patterns P. Surface roughness Ra of the planarizing layer 50 may be 10 nm or smaller.

The planarizing layer 50 may include a transparent material. That is, the visible light transmittance of the planarizing layer 50 may be about 90% or higher. The refractive index of the planarizing layer 50 may be about 1.8 to about 2.5. The planarizing layer 50 may be formed from an inorganic material, such as TiO₂, ZrO₂, TiO₂—SiO₂, SnO₂, or In₂O₃, an organic-inorganic hybrid material including the inorganic material, polyimide, or a composite material of the inorganic material and a polymer.

In detail, the planarizing layer 50 may be formed by a spin coating, dip coating, slit coating, bar coating, or spray coating method. The planarizing layer 50 is coated by the above-described coating method, and then the planarizing layer 50 may hardened by using heat treatment or a UV irradiation process.

Referring to FIG. 8, a first electrode 60, an organic light emitting layer 70, a second electrode 80, and a protecting layer 90 are sequentially stacked on the planarizing layer 50.

The first electrode 60 may be formed of a transparent electrode or a reflective electrode. When the first electrode 60 is a transparent electrode, the first electrode 60 is formed from, for example, indium tin oxide (ITO), indium zinc oxide, or tin oxide. When the first electrode 60 is a reflective electrode, the first electrode 60 is formed from, for example, silver (Ag), aluminum (Al), Nickel (Ni), platinum (Pt), or palladium (Pd). The refractive index of the first electrode 60 may be substantially the same as or smaller than that of the planarizing layer 50.

The organic light emitting layer 70 may include an organic light emitting material containing at least any one of a polyfluorene derivative, a (poly)paraphenylenevinylene derivative, a polyphenylene derivative, a polyvinylcarbazole derivative, a polythiopliene derivative, an anthracene derivative, a butadiene derivative, a tetracene derivative, a distyrylarylene derivative, a benzazole derivative, or a carbazole derivative. In addition, the organic light emitting layer 70 may include an organic light emitting material containing a dopant. For example, the dopant may include at least any one of xanthene, perylene, cumarine, rhodamine, rubrene, dicyanomethylenepyran, thiopyran, (thia)pyrilium, periflanthene derivative, indenoperylene derivative, carbostyryl, Nile red, or quinacridone.

The organic light emitting layer 70 may include at least any one of a hole injecting layer, a hole transfer layer, an electron transfer layer, or an electron injecting layer. The organic light emitting layer 70 may generate a light by using recombination of a hole and an electron provided from the first electrode 60 or the second electrode 80.

The second electrode 80 may include a translucent or reflective conductive metal. The second electrode 80 may include, for example, at least one of gold, silver, iridium, molybdenum, palladium, or platinum.

The protection layer 90 may perform a function of protecting the second electrode 80. The protecting layer 90 may include a transparent material, and be formed by using a polymeric material.

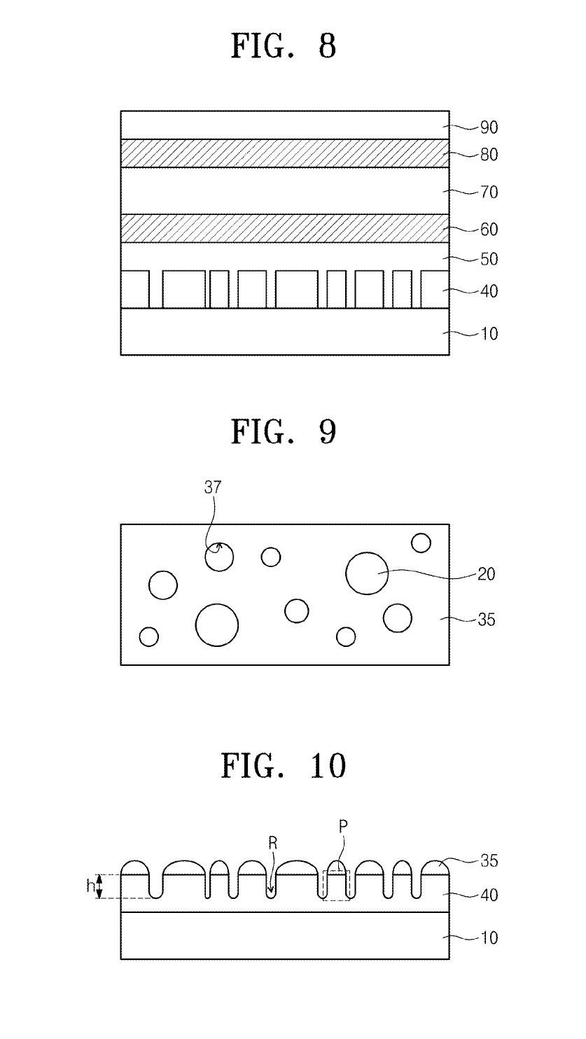

FIG. 9 is a plan view of a metal mask pattern according to another embodiment of the present invention. For simplification of description, with respect to the same configuration as a method of manufacturing an organic light emitting diode according to an embodiment of the present invention described in relation to FIGS. 2 to 4, and FIGS. 6 to 8, same reference numerals are provided and repetitive description may be omitted.

First, as described in relation to FIGS. 1, and 2 to 4, a light scattering layer 20 may be formed (S 10) on a substrate 10, and a metal mask layer 30 may be formed (S20) on the light scattering layer 20. A metal mask pattern 35 may be formed (S30) by performing a heat treatment process A on the metal mask layer 30.

Referring to FIG. 9, the metal mask pattern 35 may be a single metal film having a plurality of openings 37 exposing the light scattering layer 20. When the heat treatment process A is performed for a predetermined time on the metal mask layer 30, the metal mask pattern 35 may be formed in a type as shown in FIG. 9 in terms of planar view. Furthermore, when the heat treatment process A is performed for a sufficiently long time on the metal mask layer 30, the metal mask pattern 35 may be formed in a type as shown in FIG. 5 in terms of planar view.

Processes thereafter are the same as the method of manufacturing an organic light emitting diode according to an embodiment of the present invention described in relation to FIGS. 6 to 8.

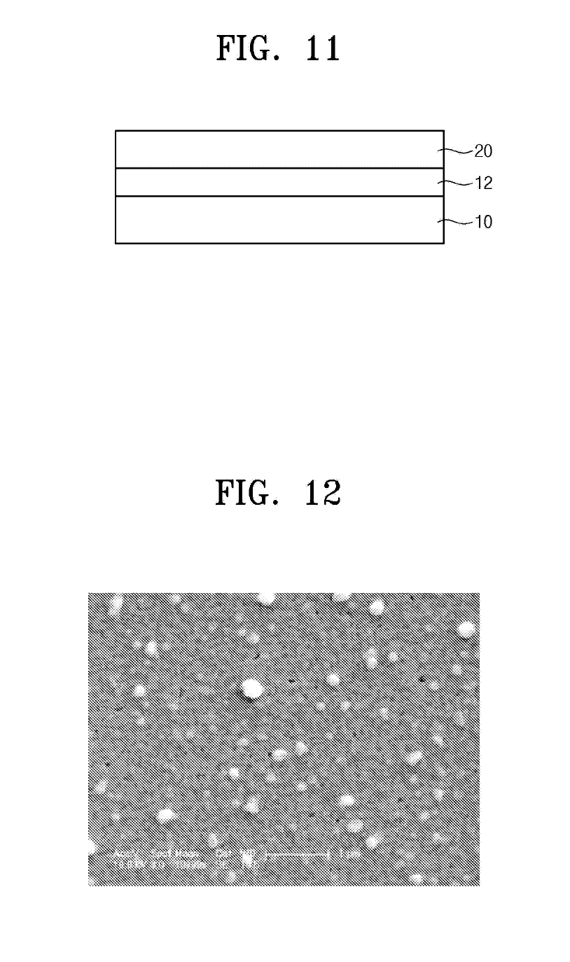

FIG. 10 is a cross-sectional view illustrating a method of manufacturing an organic light emitting diode according to another embodiment of the present invention. For simplification of description, with respect to the same configuration as a method of manufacturing an organic light emitting diode according to an embodiment of the present invention described in relation to FIGS. 2 to 4, and FIGS. 6 to 8, same reference numerals are provided and repetitive description may be omitted.

First, as described in relation to FIGS. 1, and 2 to 4, a light scattering layer 20 may be formed (S10) on the substrate 10, and a metal mask layer 30 may be formed (S20) on the light scattering layer 20. A metal mask pattern 35 may be formed (S30) by performing a heat treatment process A on the metal mask layer 30. The metal mask pattern 35 may be formed in a type as shown in FIG. 5 or FIG. 9, in terms of planar view.

Referring to FIG. 10, a nano structure 40 may be formed (S40) by patterning a light scattering layer 20 by using the metal mask pattern 35 as an etching mask. The forming of the nano structure 40 may include forming recess regions R by etching the light scattering layer 20 exposed by the openings 37 of the metal mask pattern 35.

The forming of the recess regions R may include a wet-etching the light scattering layer 20. The wet etching process may be an etching process using hydrofluoric acid, buffered oxide etchant (BOE), or an organic solvent. After the wet etching process, a part of the light scattering layer 20 under the recess regions R may be not etched and remain.

The nano structure 40 may have a plurality of nano patterns P protruding in a vertical direction to a top surface of the substrate 10 and the recess regions R may be defined by side walls of the nano patterns P. The height of the nano patterns P, which is defined as a distance between the top surface of the nano patterns P and the bottom surface of the recess regions R, may be about 150 nm to about 600 nm.

Processes thereafter are the same as the method of manufacturing an organic light emitting diode according to an embodiment of the present invention described in relation to FIGS. 7 and 8.

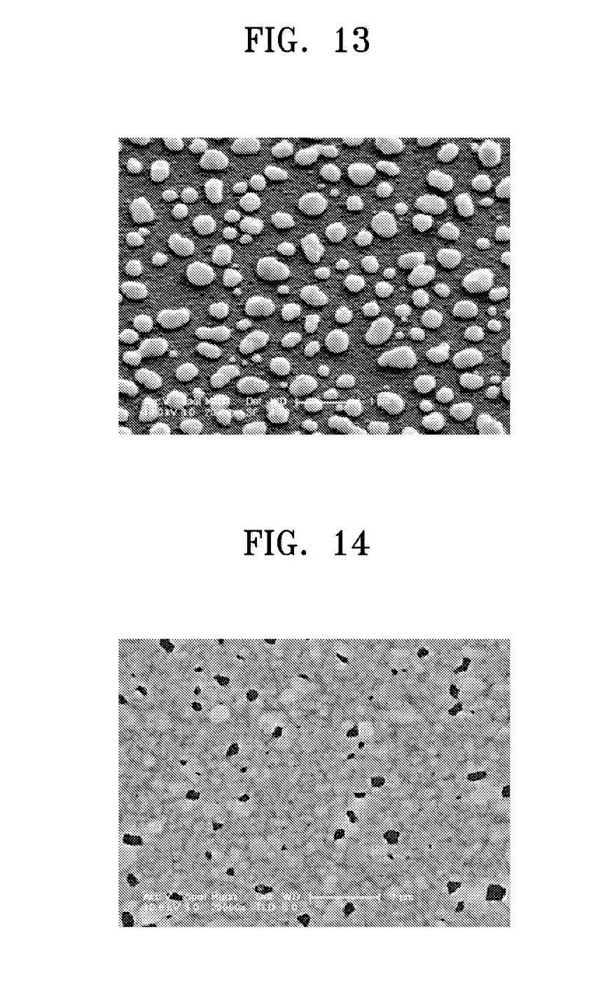

FIG. 11 is a cross-sectional view illustrating a method of manufacturing an organic light emitting diode according to another embodiment of the present invention. For simplification of description, with respect to the same configuration as a method of manufacturing an organic light emitting diode according to an embodiment of the present invention described in relation to FIGS. 2 to 4, and FIGS. 6 to 8, same reference numerals are provided and repetitive description may be omitted.

Referring to FIGS. 1 and 11, a polymer film 12 may be formed on a substrate 10, and a light scattering layer 20 may be formed (S10) on the polymer film 12. Although not shown in the drawing, the substrate 10 may include a color filter for display. The polymer film 12 may include at least one of polyacrylic, polyimide, polycarbonate, perylene, polyethylene, and polystyrene. Thereafter, as described in relation to FIGS. 1, 3, and 4, a metal mask layer 30 may be formed (S20) on the light scattering layer 20, and a metal mask pattern 35 may be formed (S30) by performing a heat treatment process A on the metal mask layer 30. When the heat treatment process A is performed at temperature of 230° C. or higher, yellowing and cracks may occur in the polymer film 12. According to a concept of the present invention, the heat treatment process A may be performed at relative low temperature of about 80° C. to about 200° C., and accordingly, the polymer film 12 may be prevented from being damaged during the heat treatment process A.

Processes thereafter are the same as the method of manufacturing an organic light emitting diode according to an embodiment of the present invention described in relation to FIGS. 6 to 8.

According to a concept of the present invention, a metal mask pattern can be easily formed at relatively low temperature. By using the metal mask pattern, a nano structure can be easily formed which includes nano patterns having a relatively high height. Accordingly, an organic light emitting diode having improved light extraction efficiency can be easily manufactured at a low cost.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of manufacturing an organic light emitting diode, comprising:
forming a light scattering layer on a substrate;
forming a metal mask layer on the light scattering layer;
forming a metal mask pattern by performing a heat treatment process on the metal mask layer;
forming a nano structure by pattering the light scattering layer by using the metal mask pattern as an etching mask; and
forming a planarizing layer to cover the nano structure on the substrate,
wherein the heat treatment process is performed at temperature of about 80° C. to about 200° C.

2. The method of claim 1, wherein the heat treatment process is performed in a vacuum state.

3. The method of claim 1, wherein the heat treatment process is performed in an inert gas atmosphere.

4. The method of claim 1, wherein the light scattering layer has a smaller refractive index than the substrate.

5. The method of claim 4, wherein the refractive index of the light scattering layer is about 1.1 to about 1.5.

6. The method of claim 5, wherein the light scattering layer comprises fluorine resin, silicone oxide, magnesium oxide, or a combination thereof.

7. The method of claim 1, wherein the nano structure comprises:
a plurality of nano patterns protruding in a vertical direction to a top surface of the substrate; and
recess regions defined by side walls of the plurality of nano patterns,
wherein a height of the plurality of nano patterns is defined as a distance between a top surface of the nano patterns and a bottom surface of the recess regions, and
the height of the nano patterns is about 150 nm to 600 nm.

8. The method of claim 7, where the metal mask pattern comprises openings exposing the light scattering layer, and
the forming of the nano structure comprises forming the recess regions by etching the light scattering layer exposed by the openings.

9. The method of claim 1, further comprising removing the metal mask pattern after the forming of the nano structure,
wherein the metal mask pattern is removed by using an acid solution.

10. The method of claim 9, wherein the acid solution comprises nitric acid, sulfuric acid, aqua regia, or phosphoric acid.

11. The method of claim 1, further comprising:
forming a first electrode on the planarizing layer;
forming an organic light emitting layer on the first electrode; and
forming a second electrode on the organic light emitting layer,
wherein the planarizing layer has substantially the same refractive index as the first electrode.

12. The method of claim 1, further comprising:
forming a first electrode on the planarizing layer;
forming an organic light emitting layer on the first electrode; and
forming a second electrode on the organic light emitting layer,
wherein the planarizing layer has a greater refractive index than the first electrode.

13. The method of claim 12, wherein the refractive index of the planarizing layer is about 1.8 to about 2.5.

14. The method of claim 1, further comprising forming a polymer film between the substrate and the light scattering layer,
wherein the polymer film comprises at least one of polyacrylic, polyimide, polycarbonate, perylene, polyethylene, and polystyrene.
